(19) United States
(12) Patent Application Publication
(10) Pub. No.: US 2006/0163622 A1
(43) Pub. Date: Jul. 27, 2006

(54) Apparatus and method for manufacturing thermal interface device having aligned carbon nanotubes

(76) Inventors: Stephen W. Montgomery, Seattle, WA (US); Barrett M. Faneuf, Olympia, WA (US); Richard W. Montgomery, Puyallup, WA (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/367,092

(22) Filed: Mar. 3, 2006

Related U.S. Application Data
(62) Division of application No. 10/607,178, filed on Jun. 25, 2003.

(51) Int. Cl. H01L 29/80; H01L 31/112

(52) U.S. Cl. 257/264

(57) ABSTRACT

A method and apparatus for manufacturing a coupon of material having aligned carbon nanotubes. The coupon having aligned carbon nanotubes may be used as a thermal interface device in a packaged integrated circuit device.

### FIELD OF THE INVENTION

The invention relates generally to the packaging of an integrated circuit die and, more particularly, to an apparatus and method for manufacturing a thermal interface device having aligned carbon nanotubes.

### BACKGROUND OF THE INVENTION

Illustrated in FIG. 1 is a conventional packaged integrated circuit device 100. The integrated circuit (IC) device 100 may, for example, comprise a microprocessor, a network processor, or other processing device, and the IC device 100 may be constructed using flip-chip mounting and Controlled Collapse Chip Connection (or “C4”) assembly techniques. The IC device 100 includes a die 110 that is disposed on a substrate 120, this substrate often referred to as the “package substrate.” A plurality of bond pads on the die 110 are electrically connected to a corresponding plurality of leads, or “lands”, on the substrate 120 by an array of connection elements 130 (e.g., solder balls, columns, etc.). Circuitry on the package substrate 120, in turn, routes the die leads to locations on the substrate 120 where electrical connections can be established with a next-level component (e.g., a motherboard, a computer system, a circuit board, another IC device, etc.). For example, the substrate circuitry may route all signal lines to a pin-grid array 125—or, alternatively, a ball-grid array—formed on a lower surface of the package substrate 120. The pin-grid (or ball-grid) array then electrically couples the die to the next-level component, which includes a mating array of terminals (e.g., pin sockets, bond pads, etc.).

During operation of the IC device 100, heat generated by the die 110 can damage the die if this heat is not transferred away from the die or otherwise dissipated. To remove heat from the die 110, the die 110 is ultimately coupled with a heat sink 170 via a number of thermally conductive components, including a first thermal interface 140, a heat spreader 150, and a second thermal interface 160. The first thermal interface 140 is coupled with an upper surface of the die 110, and this thermal interface conducts heat from the die and to the heat spreader 150. Heat spreader 150 conducts heat laterally within itself to “spread” the heat laterally outwards from the die 110, and the heat spreader 150 also conducts the heat to the second thermal interface 160. The second thermal interface 160 conducts the heat to heat sink 170, which transfers the heat to the ambient environment. Heat sink 170 may include a plurality of fins 172, or other similar features providing increased surface area, to facilitate convection of heat to the surrounding air. The IC device 100 may also include a seal element 180 to seal the die 110 from the operating environment.

The efficient removal of heat from the die 110 depends on the performance of the first and second thermal interfaces 140, 160, as well as the heat spreader 150. As the power dissipation of processing devices increases with each design generation, the thermal performance of these devices becomes even more critical. To efficiently conduct heat away from the die 110 and toward the heat sink 170, the first and second thermal interfaces 140, 160 should efficiently conduct heat in a transverse direction (see arrow 105).

At the first thermal interface, it is known to use a layer of thermal grease disposed between the die 110 and the heat spreader. 150. Thermal greases are, however, unsuitable for high power—and, hence, high heat—applications, as these materials lack sufficient thermal conductivity to efficiently remove a substantial heat load. It is also known to use a layer of a low melting point metal alloy (e.g., a solder) as the first thermal interface 140. However, these low melting point alloys are difficult to apply in a thin, uniform layer on the die 110, and these materials may also exhibit low reliability. Examples of materials used at the second thermal interface include thermally conductive epoxies and other thermally conductive polymeric materials.

### BRIEF DESCRIPTION OF THE DRAWINGS

FIG. 1 is a cross-sectional elevation view of a conventional integrated circuit package

FIG. 2 is a schematic diagram illustrating one embodiment of an apparatus for manufacturing thermal interface devices having aligned carbon nanotubes.

FIG. 3 is a block diagram illustrating one embodiment of a method for manufacturing a thermal interfaces device having aligned carbon nanotubes.

FIGS. 4A-4F are schematic diagrams illustrating an embodiment of the method for manufacturing thermal interface devices shown in FIG. 3.

FIG. 5 is a schematic diagram illustrating an embodiment of a coupon having aligned carbon nanotubes.

FIG. 6A is a perspective view of another embodiment of an apparatus for manufacturing thermal interface devices having aligned carbon nanotubes.

FIG. 6B is a plan view of a portion of the apparatus for manufacturing thermal interface devices shown in FIG. 6A.

FIG. 6C is a cross-sectional elevation view of the apparatus for manufacturing thermal interface devices shown in FIGS. 6A and 6B, as taken along line I-I of FIG. 6B.

FIG. 7 is a schematic diagram illustrating a further embodiment of an apparatus for manufacturing thermal interface devices having aligned carbon nanotubes.

FIG. 8 is a schematic diagram of a computer system including an integrated circuit device having a thermal interface device with aligned carbon nanotubes.

FIG. 9 is a perspective view of an example of a conventional carbon nanotube.

### DETAILED DESCRIPTION OF THE INVENTION

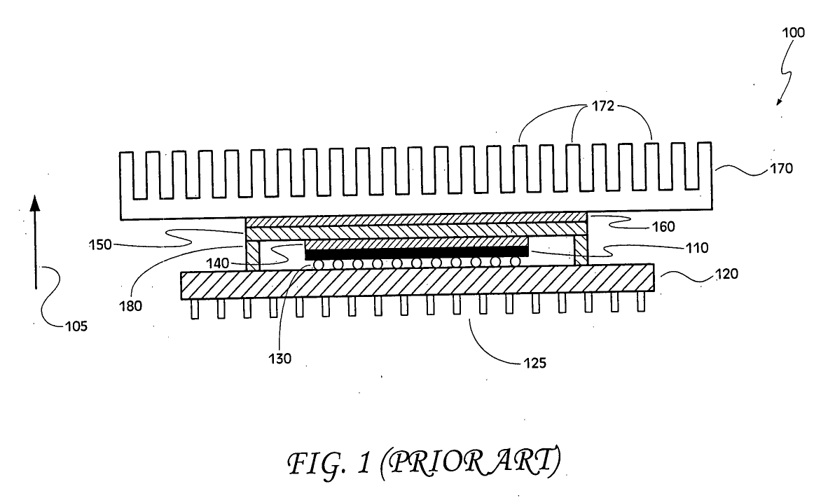

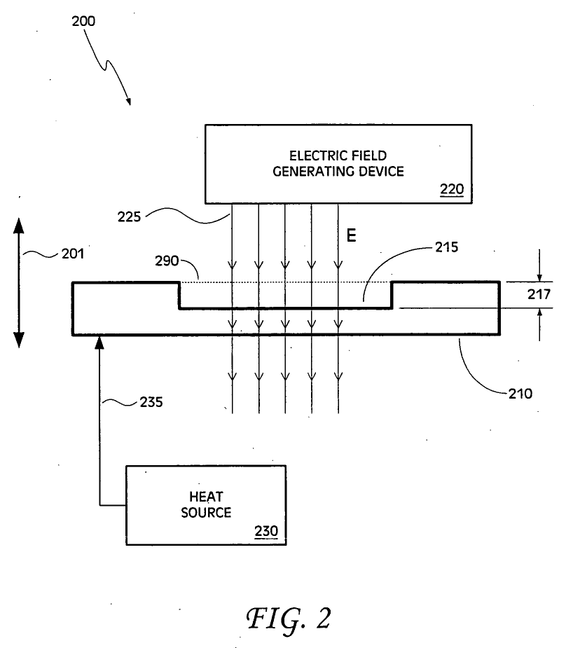

Illustrated in FIGS. 2 through 7 are embodiments of an apparatus and method for fabricating a thermal interface device having aligned carbon nanotubes. In one disclosed embodiment, the apparatus includes one or more mold cavities for receiving a solution containing carbon nanotubes. The apparatus also includes a device to apply an electric field across the mold cavities to align the carbon nanotubes prior to or during solidification of the solution. The solidified solution forms a coupon having aligned carbon nanotubes, and this coupon may be utilized as a thermal interface device in a packaged IC device, such as IC device 100 of FIG. 1 (e.g., as thermal interface devices 140 and 160). However, although the disclosed embodiments are explained in the context of manufacturing thermal interfaces devices for packaged IC chips, it should be understood that the disclosed thermal interface devices—and the apparatus and method for their production—may find application in a wide variety of applications where a thermally conductive element is needed and/or where aligned carbon nanotubes are desired (e.g., field emission displays, data storage devices, as well as other electronic and photonic devices).

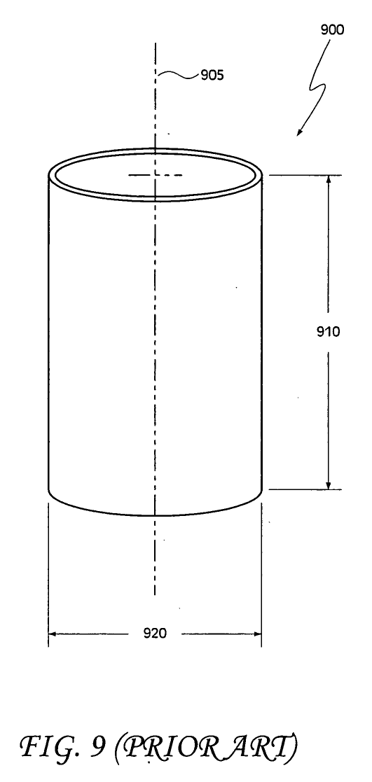

An example of a typical carbon nanotube 900 is shown in FIG. 9. The carbon nanotube is cylindrical in shape and is single walled; however, a carbon nanotube may be multi-walled. The carbon nanotube 900 extends along a primary axis 905, and the nanotube 900 has a height 910 and a diameter 920. The height 910 may be in a range of between 1 μm and 10 μm, and the diameter may be in a range of between 10 and 1000 angstroms. Carbon nanotubes are characterized by high mechanical strength, good chemical stability, and high thermal conductivity, especially in a direction along their primary axis 905.

Referring now to FIG. 2, an embodiment of an apparatus 200 for producing a thermal interface device having aligned carbon nanotubes is shown. The apparatus 200 includes a substrate 210 having a mold cavity 215. The mold cavity 215 may receive a quantity of solution 290 including carbon nanotubes, as will be explained in more detail below. The substrate 210 may be constructed from any suitable material using any suitable fabrication techniques. In one embodiment, the substrate is fabricated from a silicon material, and the mold cavity 215 may be formed using an etching process (e.g., a chemical etch process). In one embodiment, the shape and configuration of the mold cavity 215 corresponds to the desired shape of a thermal interface device for a packaged IC die, such that the structure produced by the apparatus 200 has a shape and configuration that allows the structure to be used as a thermal interface device without post-mold machining operations. The mold cavity 215 may have a depth 217 in a range of between approximately 20 μm and 150 μm.

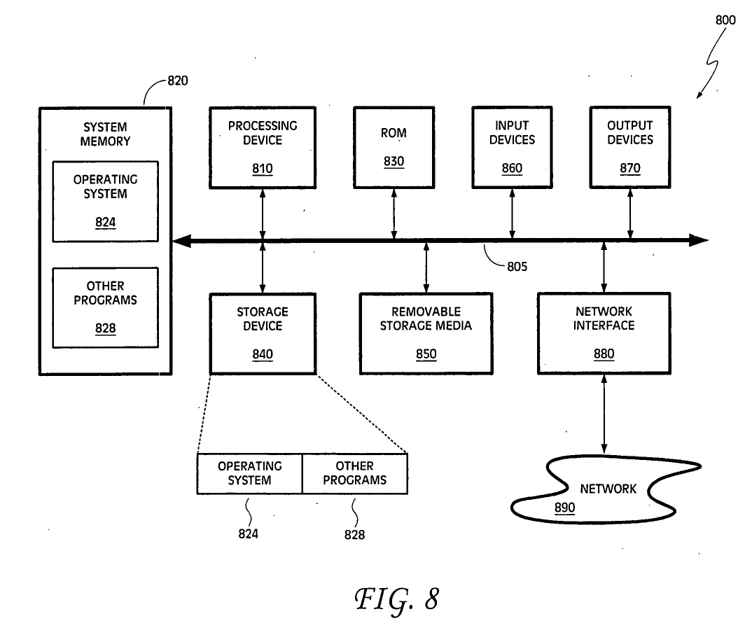

The apparatus 200 also includes an electric field generating device 220 to generate an electric field (E) 225 across the mold cavity 215 of substrate 210. When an electric field is applied to a carbon nanotube, the carbon nanotube will align itself in the direction of the electric field (i.e., referring back to FIG. 8, the primary axis 805 of carbon nanotube 800 will align itself in the direction of the electric field 225). As noted above, carbon nanotubes are excellent conductors along their primary axis. Thus, by aligning the carbon nanotubes of solution 290 in a direction parallel with the direction of the electric field 225, the solution 290, when solidified to “freeze” the carbon nanotubes in the aligned state, will form a coupon of material having high thermal conductivity in the direction of alignment of the carbon nanotubes (see arrow 201 in FIG. 2). Any suitable device may be employed to apply an electric field across the mold cavity 215, and an embodiment of such an electric field generating device 220 is disclosed below. In one embodiment, the strength of the electric field 225 provided by electric field generating device 220 is in a range of between approximately 20 kV/m to 30,000 kV/m.

In one embodiment, the apparatus 200 further includes a heat source 230. Depending upon the make-up of the solution 290, it may be desirable to apply heat 235 to the substrate 210 and mold cavity 215 to cure (or to at least accelerate curing of) the solution 290. The heat source 230 may comprise any suitable heat source or heating element (e.g., a resistance heater). The heat source 230 may raise the temperature of the solution 290 in mold cavity 215 up to a temperature of approximately 100° C. It should be understood, however, that additional heat may not be necessary to cure the solution 290, as the solution 290 may, in some embodiments, cure at room temperature.

The solution 290 generally comprises a liquid in which a volume of carbon nanotubes has been dispersed. In one embodiment, the carbon nanotubes comprise between approximately 0.2 percent and 2 percent by volume of the solution 290. The solution 290 may be agitated to promote uniform dispersion of the carbon nanotubes. In one embodiment, the solution 290 comprises a polymer that has been dissolved in a solvent, such as a non-polar solvent. For example, the solution 290 may comprise a polycarbonate or a polyurethane that has been dissolved in methylene chloride. To cure such a solution, the solvent is evaporated from the solution to form a solidified polymer. Evaporation of the solvent may occur at room temperature, or evaporation of the solvent may be accelerated by raising the temperature of the solution (e.g., using heat source 230, as described above). In another embodiment, the solution 290 also includes a surfactant to prevent clumping of the carbon nanotubes.

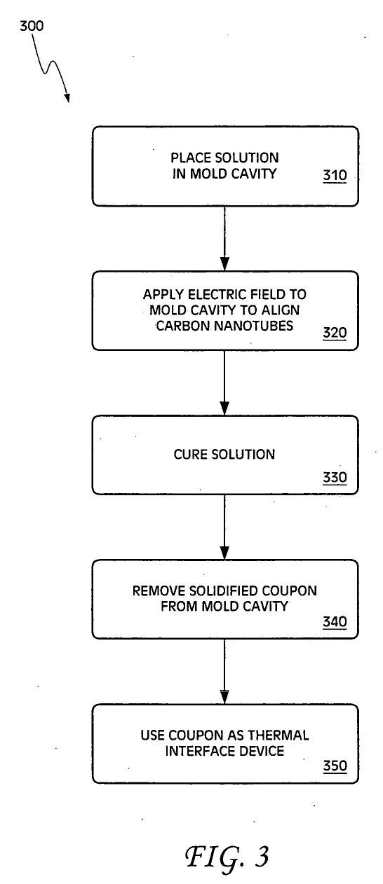

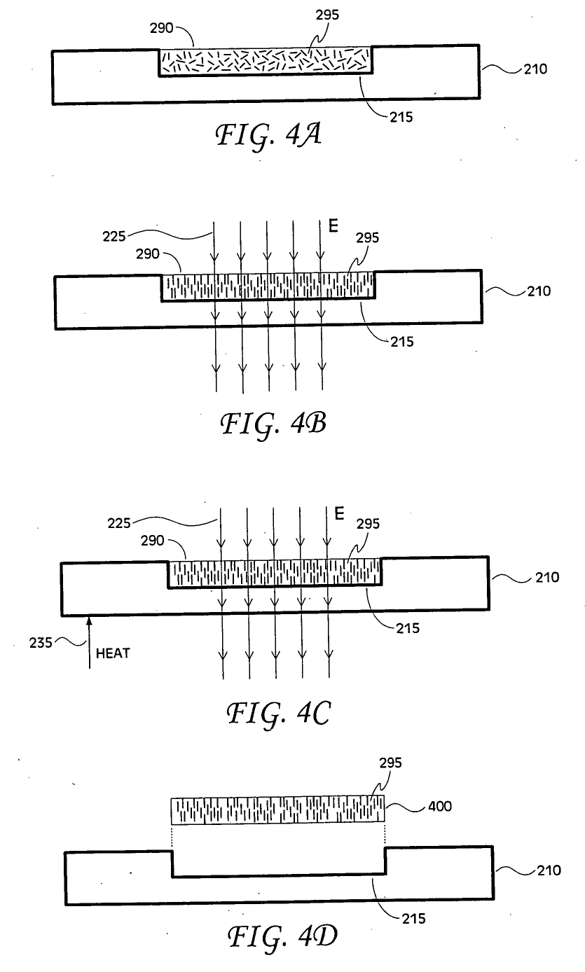

Illustrated in FIG. 3 is an embodiment of a method 300 for manufacturing a thermal interface device having aligned carbon nanotubes, as may be performed using the apparatus 200 of FIG. 2. Also, illustrated in FIGS. 4A through 4F are various stages of the method 300 of FIG. 3, and reference should be made to these figures along with FIG. 3, as called out in the text.

Referring now to block 310 in FIG. 3, solution is placed in the mold cavity. This is shown in FIG. 4A, where a volume of solution 290 has been disposed in the mold cavity 215 of substrate 210. The random distribution of the carbon nanotubes 295 is illustrated schematically in FIG. 4A. As shown at block 320, an electric field is then applied to the solution in the mold cavity to align the carbon nanotubes dispersed within the solution along the direction of the electric field (i.e., the primary axis of the carbon nanotubes is aligned parallel to the direction of the electric field, as described above). This is illustrated in FIG. 4B, where an electric field (E) 225 has been applied across the mold cavity 215 to align the carbon nanotubes 295 in the direction of the electric field 225.

Referring to block 330, the solution in the mold cavity is cured, such that the carbon nanotubes 295 are “frozen” in their aligned states. In one embodiment, as shown in FIG. 4C, heat 235 is applied to the substrate 210 and mold cavity 215 to elevate the temperature of the solution 290 in the mold cavity. In other embodiments, alternative means for curing the solution 290 may be employed, such as exposing the solution to ultraviolet light or applying a chemical additive or spray to the solution. The electric field 225 may be maintained throughout the cure time or, alternatively, the electric field 225 may be removed when the solution 290 has been at least partially cured to a state (e.g., a gel state) wherein the carbon nanotubes 295 remain in their aligned positions. With reference now to block 340 and FIG. 4D, the solidified solution is removed from the mold cavity, the solidified solution forming a coupon 400 having aligned carbon nanotubes 295.

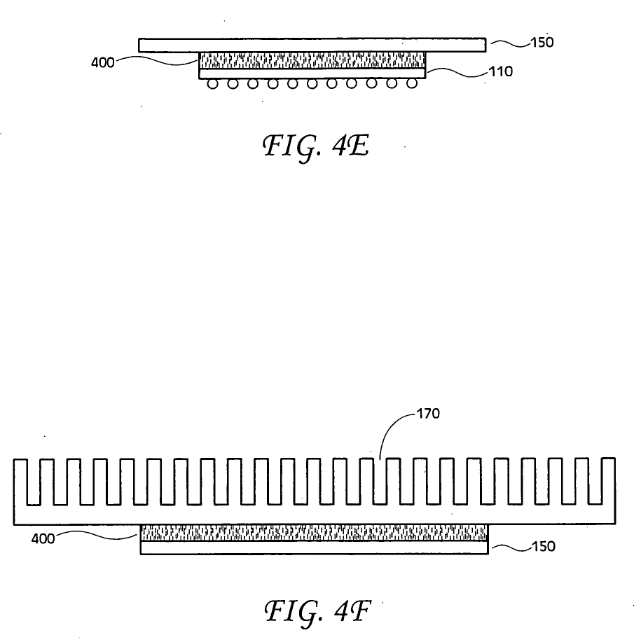

In one embodiment, the thickness of the coupon 400 is generally equal to the depth 217 of the mold cavity 215, as shown in FIGS. 2 and 4A-4D. However, in other embodiments, the thickness of the coupon 400 may exceed the depth 217 of the mold cavity 215. This is illustrated in FIG. 5, where the coupon 400 has a thickness 402 that is greater than the depth 217 of the mold cavity 215. The thickness 402 of coupon 400 is equal to the mold cavity depth 217 plus the height 404 that the coupon 400 extends above the upper. surface of the substrate 210. The height 404 of the coupon 400 above the upper surface of the substrate 210 is determined by the contact angle 406, which is a function of the material properties (e.g., viscosity) of the solution 290 used to form coupon 400. The thickness of the coupon 400 may, of course, be less than the mold cavity depth 217. At its lower limit, the thickness 402 of the coupon 400 has a magnitude approximately equal to the length of the carbon nanotubes 295 dispersed in the solution 290 (or average length, as the carbon nanotubes in any single fabrication batch may exhibit some variation in their lengths). In one embodiment, the coupon 400 has a thickness 402 in a range between approximately 20 μm and 150 μm.

Referring back to FIG. 3, in a further embodiment, the solidified coupon 400 is used as a thermal interface device, as shown at block 350. In one embodiment, as shown in FIG. 4E, the solidified coupon 400 is used as a thermal interface between the IC die 110 and heat spreader 150 of the packaged IC device 100 shown in FIG. 1. In another embodiment, as shown in FIG. 4F, the solidified coupon 400 is used as a thermal interface between the heat spreader 150 and the heat sink 170 of the packaged IC device 100. It should be understood that each of FIGS. 4E and 4F represents but one example of the use of the solidified coupon 400 and, further, that such a coupon of material having aligned carbon nanotubes may find use in a wide variety of applications requiring a thermal interface device and/or aligned carbon nanotubes.

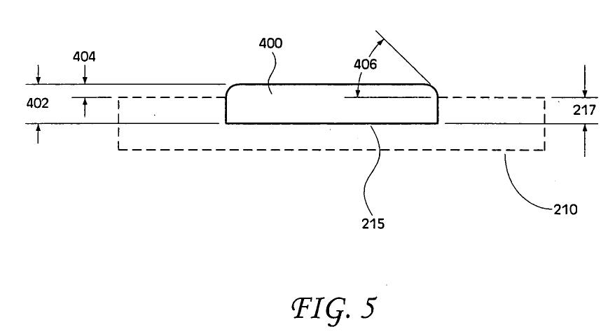

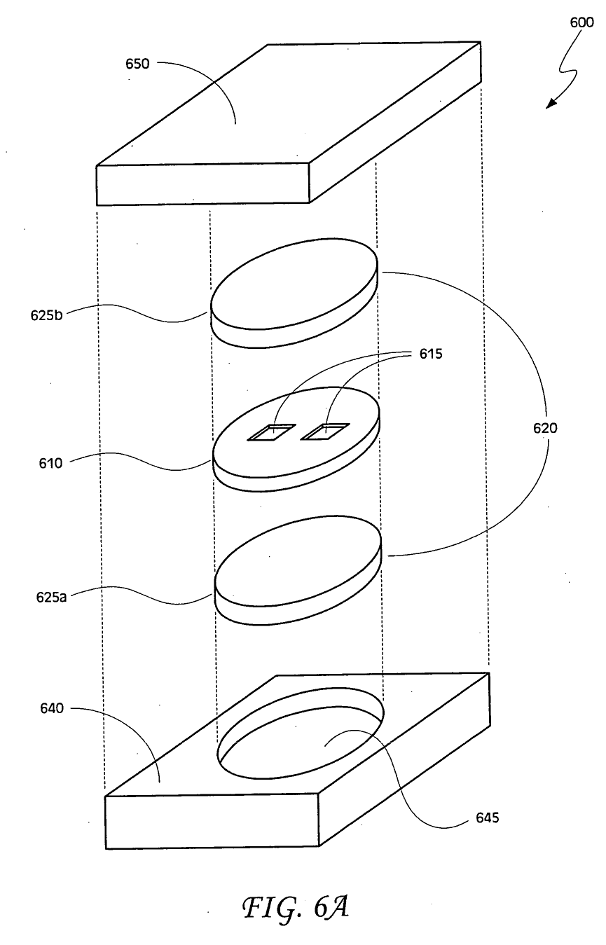

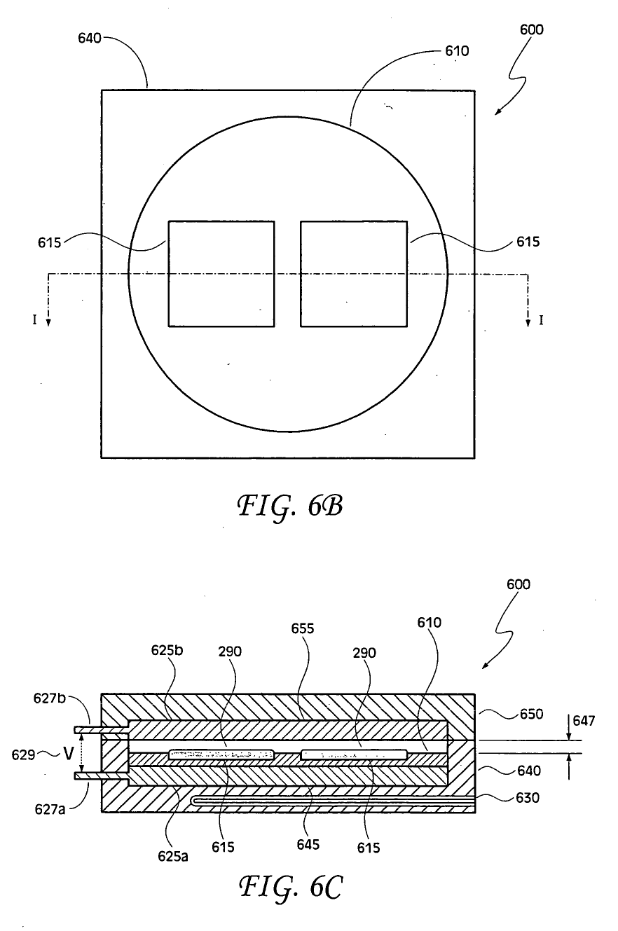

Illustrated in FIGS. 6A through 6C is another embodiment of an apparatus 600 for manufacturing a thermal interface device having aligned carbon nanotubes. A perspective view of the apparatus 600 is shown in FIG. 6A, whereas a plan view of the apparatus 600 (with upper housing 650 and second plate 625b removed) is shown in FIG. 6B and a cross-sectional elevation view of this apparatus is shown in FIG. 6C.

With reference now to FIGS. 6A through 6C, the apparatus 600 includes a substrate 610 having one or more a mold cavities 615, an electric field generating device 620 including a first plate 625a and a second plate 625b, as well as a lower housing 640 and an upper housing 650. The first plate 625a is disposed in a cavity 645 formed in the lower housing 640, and the substrate 610 is also disposed within the cavity 645 of lower housing 640 on top of the first plate 625a. The second plate 625b is disposed within a cavity 655 formed in the upper housing 650, and the upper housing 650 may be engaged with the lower housing 640, as shown in FIG. 6C.

Each mold cavity 615 in the substrate 610 may receive a quantity of solution 290 (see FIG. 6C) including carbon nanotubes. The substrate 610 may be constructed from any suitable material using any suitable fabrication techniques. In one embodiment, the substrate is fabricated from a silicon material, and the mold cavities 615 may be formed using an etching process (e.g., a chemical etch process). In one embodiment, the shape and configuration of each mold cavity 615 corresponds to the desired shape of a thermal interface device for a packaged IC die, such that the coupons fabricated by the apparatus 600 have a shape and configuration that allows these coupons to be used as a thermal interface devices without post-mold machining operations. The mold cavities 615 may each have a depth in a range of between approximately 20 μm and 150 μm. Note that, when the lower and upper housings 640, 650 are engaged, as shown in FIG. 6C, a clearance space 647 is provided between the substrate 610 and the second plate 625b. This clearance gap 647 allows the solution 290 in mold cavities 615 to extend above the upper surface of the substrate 610 (see FIG. 5 and accompanying text).

The electric field generating device 620 includes a first plate 625a and a second plate 625b, as noted above. Each of the plates 625a, 625b may be constructed from any suitable material, such as, for example, a copper material. The first plate 625a is positioned on one side (e.g., a lower side) of the substrate 610, and the second plate 625b is positioned on an opposing side (e.g., an upper side) of the substrate 610. The first plate 625a includes an electrode 627a extending out of the lower housing 640 and, similarly, the second plate 625b includes an electrode 627b extending out of the lower housing 640 (see FIG. 6C). When a voltage (V) 629 is applied between the electrodes 627a, 627b of the first and second plates 625a, 625b, an electric field is created between the first and second plates 625a-b. This mold cavities 615 on substrate 610 lie within this electric field and, therefore, any solution placed in the mold cavities 615 may be subjected to the electric field to align the carbon nanotubes in the solution. In essence, the first and second plates 625a, 625b comprise a parallel-plate capacitor. In one embodiment, the voltage 629 applied across the electrodes 627a, 627b may have a magnitude in a range up to approximately 300 V. The strength of the electric field generated between the first and second plates 625a, 625b may be within a range of approximately 20 kV/m to 30,000 kV/m.

In one embodiment, which is shown in FIG. 6C, the apparatus 600 further includes a heat source 630. As noted above, depending upon the make-up of the solution 290, it may be desirable to apply heat to the substrate 610 and mold cavities 615 to cure (or to at least accelerate curing of) the solution 290. The heat source 630 may comprise any suitable heat source or heating element (e.g., a resistance heater). The heat source 630 may raise the temperature of the solution 290 in mold cavities 615 up to a temperature of approximately 100° C. Once again, it should be understood that additional heat may not be necessary to cure the solution 290, as the solution may, in some embodiments, cure at room temperature (or cure by other alternative means, as noted above).

The apparatus 600 shown and described with respect to FIGS. 6A through 6C generally functions in a manner similar to the apparatus 200 shown and described above in FIGS. 2, 3, 4A-4D, and 5. A solution 290 containing carbon nanotubes can be placed in the mold cavities 615 and solidified in the presence of an electric field to produce one or more coupons, each coupon having aligned carbon nanotubes. Such a coupon of material having aligned carbon nanotubes may be employed as a thermal interface device in a packaged IC die.

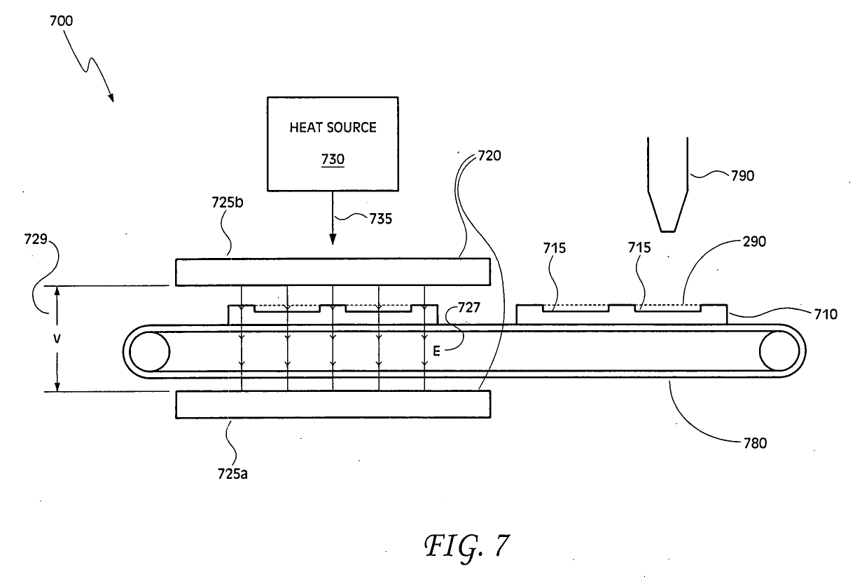

Illustrated in FIG. 7 is a further embodiment of an apparatus for fabricating thermal interface devices having aligned carbon nanotubes. The apparatus 700 of FIG. 7 may be suited to a production setting, where it may be desirable to manufacture coupons having aligned carbon nanotubes in relatively larger quantities. The apparatus 700 generally functions in a manner similar to the apparatuses 200, 600 described above with respect to FIGS. 2, 3, 4A-4D, 5, and 6A-6C, and a description of some like elements may not be repeated in the following description of FIG. 7.

Referring to FIG. 7, the apparatus 700 includes one or more substrates 710, each of the substrate 710 including one or more mold cavities 715. Each mold cavity 715 on one of the substrates 710 may receive a quantity of solution 290 including carbon nanotubes. The solution 290 may be dispensed into a mold cavity 715 by a nozzle 790 or other liquid dispensing device (e.g., syringe, dropper, etc.). The substrates 710 may be constructed from any suitable material using any suitable fabrication techniques. In one embodiment, each substrate is fabricated from a silicon material, and the mold cavities 715 may be formed using an etching process (e.g., a chemical etch process). In one embodiment, the shape and configuration of each mold cavity 715 on a substrate 710 corresponds to the desired shape of a thermal interface device for a packaged IC die, such that the coupons fabricated by the apparatus 700 have a shape and configuration that allows these coupons to be used as a thermal interface devices without post-mold machining operations. The mold cavities 715 may each have a depth in a range of between approximately 20 μm and 150 μm.

The substrates 710 are carried on a conveyor 780 or other suitable motion system. After solution 290 has been disposed in the mold cavities 715 of a substrate 710, the conveyor 780 moves that substrate within an electric field (E) 727 generated by an electric field generating device 720. In one embodiment, the electric field generating device comprises a first plate 725a positioned below the conveyor 780 (or below the substrates 710) and a second plate 725b positioned above the substrate 710 on the conveyor 780 and opposing the first plate 725a. When a voltage (V) 729 is applied between the first and second plates 725a, 725b, the electric field 727 is created between these two plates. In one embodiment, the voltage 729 applied between the first and second plates 725a, 725b may have a magnitude in a range up to approximately 300 V. The strength of the electric field 727 generated between the first and second plates 725a, 725b may be within a range of approximately 20 kV/m to 30,000 kV/m.

In one embodiment, the apparatus 700 further includes a heat source 730. As previously noted, depending upon the make-up of the solution 290, it may be desirable to apply heat 735 to the substrates 710 and mold cavities 715 to cure (or to at least accelerate curing of) the solution 290. The heat source 730 may comprise any suitable heat source or heating element (e.g., a resistance heater). The heat source 730 may raise the temperature of the solution 290 in mold cavities 715 up to a temperature of approximately 100° C. Again, as noted above, it may not be necessary to cure the solution 290, as the solution may, in some embodiments, cure at room temperature (or cure by other alternative means).

An IC device having a thermal interface comprising a coupon with aligned carbon nanotubes—e.g., the coupon with aligned carbon nanotubes 400 shown in FIGS. 4E and 4F—may find application in any type of computing system or device. An embodiment of such a computer system is illustrated in FIG. 8.

Referring to FIG. 8, the computer system 800 includes a bus 805 to which various components are coupled. Bus 805 is intended to represent a collection of one or more buses—e.g., a system bus, a Peripheral Component Interface (PCI) bus, a Small Computer System Interface (SCSI) bus, etc.—that interconnect the components of computer system 800. Representation of these buses as a single bus 805 is provided for ease of understanding, and it should be understood that the computer system 800 is not so limited. Those of ordinary skill in the art will appreciate that the computer system 800 may have any suitable bus architecture and may include any number and combination of buses.

Coupled with bus 805 is a processing device (or devices) 810. The processing device 810 may comprise any suitable processing device or system, including a microprocessor, a network processor, an application specific integrated circuit (ASIC), or a field programmable gate array (FPGA), or similar device. In one embodiment, the processing device 810 comprises an IC device including a coupon having aligned carbon nanotubes (e.g., the coupon with aligned carbon nanotubes 400 shown in each of FIGS. 4E and 4F). However, it should be understood that the disclosed thermal interface devices comprising a composite CNT structure may find use in other types of IC devices (e.g., memory devices).

Computer system 800 also includes system memory 820 coupled with bus 805, the system memory 820 comprising, for example, any suitable type of random access memory (e.g., dynamic random access memory, or DRAM). During operation of computer system 800 an operating system 824, as well as other programs 828, may be resident in the system memory 820. Computer system 800 may further include a read-only memory (ROM) 830 coupled with the bus 805. During operation, the ROM 830 may store temporary instructions and variables for processing device 810, and ROM 830 may also have resident thereon a system BIOS (Basic Input/Output System). The computer system 800 may also include a storage device 840 coupled with the bus 805. The storage device 840 comprises any suitable non-volatile memory—such as, for example, a hard disk drive—and the operating system 824 and other programs 828 may be stored in the storage device 840. Further, a device 850 for accessing removable storage media (e.g., a floppy disk drive or CD ROM drive) may be coupled with bus 805.

The computer system 800 may include one or more input devices 860 coupled with the bus 805. Common input devices 860 include keyboards, pointing devices such as a mouse, and scanners or other data entry devices. One or more output devices 870 may also be coupled with the bus 805. Common output devices 870 include video monitors, printing devices, and audio output devices (e.g., a sound card and speakers). Computer system 800 further comprises a network interface 880 coupled with bus 805. The network interface 880 comprises any suitable hardware, software, or combination of hardware and software capable of coupling the computer system 800 with a network (or networks) 890.

It should be understood that the computer system 800 illustrated in FIG. 8 is intended to represent an exemplary embodiment of such a computer system and, further, that this computer system may include many additional components, which have been omitted for clarity and ease of understanding. By way of example, the computer system 800 may include a DMA (direct memory access) controller, a chip set associated with the processing device 810, additional memory (e.g., a cache memory), as well as additional signal lines and buses. Also, it should be understood that the computer system 800 may not include all of the components shown in FIG. 8.

Embodiments of a method 300 and apparatuses 200, 600, 700 for fabricating thermal interface devices having aligned carbon nanotubes having been described herein, those of ordinary skill in the art will appreciate the advantages of the disclosed embodiments. The disclosed apparatuses 200, 600, 700 allow for the manufacture of thermal interface devices with aligned carbon nanotubes that provide high thermal conductivity. These apparatuses for fabricating a coupon with aligned carbon nanotubes are relatively simple and low cost to implement in a production environment. Further, the disclosed method and apparatuses can be used to fabricate a stand-alone coupon of thermally conductive material that may be utilized as a thermal interface in the packaging of an IC die; however, the use of such a stand-alone coupon does not necessitate exposure of the die to high temperatures or severe and potentially damaging chemical environments.

The foregoing detailed description and accompanying drawings are only illustrative and not restrictive. They have been provided primarily for a clear and comprehensive understanding of the disclosed embodiments and no unnecessary limitations are to be understood therefrom. Numerous additions, deletions, and modifications to the embodiments described herein, as well as alternative arrangements, may be devised by those skilled in the art without departing from the spirit of the disclosed embodiments and the scope of the appended claims.

1-18. (canceled)

19. An apparatus comprising:
a substrate including a mold cavity, the mold cavity to receive a solution; and
a device to apply an electric field to the mold cavity.

20. The method of claim 19, wherein the mold cavity has a shape corresponding to a shape of a thermal interface device for a packaged integrated circuit device.

21. The apparatus of claim 19, wherein the device to apply the electric field comprises:
a first plate disposed on one side of the substrate; and
a second plate disposed on an opposing side of the substrate;
wherein a voltage applied between the plates generates the electric field.

22. The apparatus of claim 21, further comprising a motion system, the motion system to move the substrate into a position between the first and second plates.

23. The apparatus of claim 21, wherein each of the first and second plates is constructed from a copper material.

24. The apparatus of claim 21, wherein the voltage has a magnitude in a range up to approximately 300 V.

25. The apparatus of claim 21, wherein the electric field has a strength in a range of approximately 20 kV/m to 30,000 kV/m.

26. The apparatus of claim 19, further comprising a heating element to heat the solution in the mold cavity.

27. The apparatus of claim 26, wherein the heating element raises a temperature of the solution in the mold cavity in a range up to approximately 100° C.

28. The apparatus of claim 19, wherein the substrate comprises a silicon substrate.

29. The apparatus of claim 28, wherein the mold cavity is formed in the silicon substrate using an etching process.

30. The apparatus of claim 19, wherein the mold cavity has a depth of between approximately 20 μm and 150 μm.

31. The apparatus of claim 19, wherein the mold cavity has a depth equal to a length of carbon nanotubes dispersed in the solution.

32. An apparatus comprising:
a lower housing;
an upper housing;
a first plate disposed on the lower housing;
a substrate disposed on the first plate, the substrate having mold cavity, the mold cavity to receive a solution including carbon nanotubes;
a second plate disposed in the upper housing, the second plate overlying the substrate when the upper housing is engaged with the lower housing;
wherein the carbon nanotubes in the solution align with an electric field generated between the first and second plates.

33. The method of claim 32, wherein the mold cavity has a shape corresponding to a shape of a thermal interface device for a packaged integrated circuit device.

34. The apparatus of claim 32, wherein each of the first and second plates is constructed from a copper material.

35. The apparatus of claim 32, wherein the electric field is generated by applying a voltage between the first and second plates having a magnitude in a range up to approximately 300 V.

36. The apparatus of claim 32, wherein the electric field has a strength in a range of approximately 20 kV/m to 30,000 kV/m.

37. The apparatus of claim 32, further comprising a heating element thermally coupled with the lower housing to heat the solution in the mold cavity.

38. The apparatus of claim 37, wherein the heating element raises a temperature of the solution in the mold cavity in a range up to approximately 100° C.

39. The apparatus of claim 32, wherein the substrate comprises a silicon substrate.

40. The apparatus of claim 39, wherein the mold cavity is formed in the silicon substrate using an etching process.

41. The apparatus of claim 32, wherein the mold cavity has a depth of between approximately 20 μm and 150 μm.

42. The apparatus of claim 32, wherein the mold cavity has a depth equal to a length of the carbon nanotubes in the solution.

43-59. (canceled)
